(19) United States
(12) Patent Application Publication
(10) Pub. No.: US 2026/0095176 A1
(43) Pub. Date: Apr. 2, 2026

(54) Gate Driver Circuit, Motor Driving Device Using the Same, and Electronic Apparatus

(71) Applicant: ROHM CO., LTD., Kyoto-shi (JP)

(72) Inventor: Hisashi SUGIE, Kyoto-shi (JP)

(21) Appl. No.: 19/339,594

(22) Filed: Sep. 25, 2025

(30) Foreign Application Priority Data
Sep. 30, 2024 (JP) 2024-171371
Apr. 28, 2025 (JP) 2025-074585

(51) Int. Cl. H03K 17/687; H02M 1/08; H02M 7/5387

(52) U.S. Cl. CPC H03K 17/6871; H02M 1/08; H02M 7/5387; H03K 2217/0063; H03K 2217/0072

(57) ABSTRACT

A first output sensor asserts a first output detection signal when an output voltage of a switching circuit or an output stage drops to a first threshold voltage. When the switching circuit is in a source mode or when the output stage is in a current source mode, the control circuit sets a high-side gate current that a high-side driver sinks from a gate of a high-side transistor to a first current amount in response to an instruction to turn off the high-side transistor. The control circuit sets the high-side gate current to a second current amount that is less than the first current amount in response to an assertion of the first output detection signal.

### CROSS REFERENCE TO RELATED APPLICATIONS

The present invention claims priority under 35 U.S.C. § 119 to Japanese Application No. 2024-171371, filed Sep. 30, 2024, and Japanese Application No. 2025-074585, filed Apr. 28, 2025, the entire contents of which being incorporated herein by reference.

### TECHNICAL FIELD

The present disclosure relates to a gate driver circuit.

### BACKGROUND

Half-bridge circuits, H-bridge circuits, and three-phase bridge circuits (hereinafter collectively referred to as switching circuits) using power transistors are used in motor driver circuits, DC/DC converters, power conversion devices, etc.

### Prior Art Document

### Patent Document

[Patent document 1] International Publication No. WO 2022/259780.

### BRIEF DESCRIPTION OF THE DRAWINGS

FIG. 1 is a circuit diagram illustrating the switching of a switching circuit.

FIG. 2 is an operational waveform diagram of the switching circuit in FIG. 1.

FIG. 3 is a circuit diagram of a switching circuit according to an embodiment.

FIG. 4 is a waveform diagram illustrating an operation of the switching circuit in FIG. 3.

FIG. 5 is a circuit diagram of a switching circuit according to a modification example 1.

FIG. 6 is a waveform diagram illustrating an operation of the switching circuit in FIG. 5.

FIG. 7 is a circuit diagram of a switching circuit according to a modification example 2.

FIG. 8 is a waveform diagram illustrating an operation of the switching circuit in FIG. 7.

FIG. 9 is a circuit diagram of a switching circuit according to a modification example 3.

FIG. 10 is a circuit diagram of a switching circuit according to a modification example 4.

FIG. 11 is a circuit diagram of a switching circuit according to a modification example 5.

FIG. 12 is a circuit diagram of a motor driving device according to an embodiment.

### DETAILED DESCRIPTION OF THE EMBODIMENTS

### Overview of Embodiments

An overview of some exemplary embodiments of the present disclosure is illustrated. This overview serves as a preface to a detailed illustration that follows, is intended to provide a basic understanding of embodiments by simplifying some concepts of one or more embodiments and is not intended to limit the scope of the invention or disclosure. For convenience, “an embodiment” may be used to refer to one embodiment (implementation example or modification example) or multiple embodiments (implementation examples or modification examples) disclosed in this specification.

This overview is not an exhaustive overview of all possible embodiments and is intended to neither identify essential elements of all embodiments nor delineate the scope of some or all aspects. Its sole purpose is to present some concepts of one or more embodiments in a simplified form as a preface to the more detailed illustration that is presented later.

A gate driver circuit, according to an embodiment, drives a high-side transistor and a low-side transistor that constitute a switching circuit (output stage). The gate driver circuit comprises a high-side driver that drives the high-side transistor, a low-side driver that drives the low-side transistor, a first output sensor that asserts a first output detection signal when an output voltage of the switching circuit (output stage) drops to a first threshold voltage, and a control circuit that controls the high-side driver and low-side driver. When the switching circuit (output stage) is in a source mode (current source mode), the control circuit sets a high-side gate current that the high-side driver sinks from a gate of the high-side transistor to a first current amount in response to an instruction to turn off the high-side transistor, and sets the high-side gate current to a second current amount that is less than the first current amount in response to an assertion of the first output detection signal.

In a transition from a high output state to a low output state (or a high impedance state), during the transition of the output voltage from a high voltage to a low voltage, a drain current flowing through the high-side transistor (hereinafter referred to as a high-side current) changes, and after the output voltage transition is complete, the high-side current becomes substantially constant. In the above configuration, an assertion of the first output detection signal indicates the completion of the output voltage transition. With this configuration, when the switching circuit (output stage) operates in the source mode (current source mode), during an interval wherein the high-side current is substantially constant after the transition is completed, by increasing the high-side gate current, a turn-off time can be shortened, and power consumption can be reduced. Additionally, during a period in which the high-side current changes during the transition of the output voltage, by reducing the high-side gate current, a rate of change of the high-side current can be lowered, and EMI can be suppressed. Additionally, a negative voltage generated at the output can be suppressed.

In an embodiment, the gate driver circuit may further comprise a second output sensor that asserts a second output detection signal when the output voltage drops to a second threshold that is lower by a predetermined voltage than an input voltage of the switching circuit (output stage). The control circuit may set the high-side gate current to a third current amount that is less than the first current amount in response to an assertion of the second output detection signal.

During the interval wherein the high-side current is substantially constant, by switching a current amount of the high-side gate current in two stages, the first current amount can be increased, the turn-off time can be further shortened, and power consumption can be reduced.

In an embodiment, the gate driver circuit may further comprise a first delay circuit that delays the second output detection signal. The control circuit may set the high-side gate current to the third current amount in response to an assertion of the delayed second output detection signal.

As a result, an interval during which the high-side gate current is at the first current amount can be extended by an amount of delay time, so the turn-off time can be further shortened.

In an embodiment, the gate driver circuit may further comprise a third output sensor that asserts a third output detection signal when the output voltage of the switching circuit (output stage) rises to a third threshold voltage. When the switching circuit (output stage) is in a sink mode (current sink mode), the control circuit may set the low-side gate current that the low-side driver sinks from a gate of the low-side transistor to a fourth current amount in response to an instruction to turn off the low-side transistor, and may set the low-side gate current to a fifth current amount that is less than the fourth current amount in response to an assertion of the third output detection signal.

In a transition from the low output state to the high output state (or the high impedance state), during the transition of the output voltage from the low voltage to the high voltage, a drain current flowing through the low-side transistor (hereinafter referred to as a low-side current) changes, and after the output voltage transition is complete, the low-side current becomes substantially constant. In the above configuration, an assertion of the third output detection signal indicates the completion of the output voltage transition. When the switching circuit (output stage) operates in the sink mode (current sink mode), during an interval when the low-side current is substantially constant after the output voltage transition is completed, by increasing the low-side gate current, the turn-off time can be shortened, and power consumption can be reduced. Additionally, during a period in which the low-side current changes during the transition of the output voltage, by reducing the low-side gate current, a rate of change of the low-side current can be lowered, and EMI can be suppressed.

In an embodiment, the gate driver circuit may further comprise a fourth output sensor that asserts a fourth output detection signal when the output voltage rises to a fourth threshold, which is lower by a predetermined voltage than the input voltage of the switching circuit (output stage). For example, when the output stage is in the current sink mode, the control circuit may set the low-side gate current to a fifth current amount that is less than the fourth current amount in response to an assertion of the fourth output detection signal.

During an interval when the low-side current is substantially constant, by switching a current amount of the low-side gate current in two stages, the fourth current amount can be increased, the turn-off time can be further shortened, and power consumption can be reduced.

In an embodiment, the gate driver circuit may further comprise a second delay circuit that delays the fourth output detection signal. For example, when the output stage is in the current sink mode, the control circuit may set the low-side gate current to the fifth current amount in response to an assertion of the delayed fourth output detection signal.

As a result, an interval during which the low-side gate current is at the fourth current amount can be extended by an amount of the delay time, so the turn-off time can be further shortened.

In an embodiment, the gate driver circuit may further comprise a low-side off sensor that asserts a low-side off detection signal when a gate-source voltage of the low-side transistor falls below a predetermined threshold level, and a low-side off fixed switch connected between a gate and a source of the low-side transistor. When the output stage is in the current source mode, the control circuit may turn on the low-side off fixed switch in response to an assertion of the low-side off detection signal. As a result, self-turn-on of the low-side transistor can be prevented.

In an embodiment, when the output stage is in the current sink mode, the control circuit may set the low-side gate current that the low-side driver sinks from a gate of the low-side transistor to the fourth current amount in response to the instruction to turn off the low-side transistor, and may turn on the low-side off fixed switch in response to the assertion of the low-side off detection signal.

In the transition from the low output state to the high output state (or the high impedance state), when in the current source mode, the output voltage is kept at a voltage near the ground voltage, so the fluctuations of the drain current of the low-side transistor are small. Therefore, by sinking the low-side gate current of the fourth current amount until the low-side transistor is completely turned off, the low-side transistor can be turned off in a short time.

A gate driver circuit according to an embodiment, drives a high-side transistor and a low-side transistor that constitute a switching circuit (output stage). The gate driver circuit comprises a high-side driver that drives the high-side transistor, a low-side driver that drives the low-side transistor, a third output sensor that asserts a third output detection signal when the output voltage of the switching circuit (output stage) rises to a third threshold voltage, and a control circuit that controls the high-side driver and the low-side driver. When the switching circuit (output stage) is in a sink mode (current sink mode), the control circuit sets the low-side gate current that the low-side driver sinks from a gate of the low-side transistor to a fourth current amount in response to an instruction to turn off the low-side transistor, and sets the low-side gate current to a fifth current amount that is less than the fourth current amount in response to an assertion of the third output detection signal.

In an embodiment, the gate driver circuit may further comprise a fourth output sensor that asserts a fourth output detection signal when the output voltage rises to a fourth threshold that is lower by a predetermined voltage than the input voltage of the switching circuit (output stage). The control circuit may set the low-side gate current to a fifth current amount that is less than the fourth current amount in response to the assertion of the fourth output detection signal.

In an embodiment, the gate driver circuit may further comprise a second delay circuit that delays the fourth output detection signal. The control circuit may set the low-side gate current to the fifth current amount in response to an assertion of the delayed fourth output detection signal.

In an embodiment, the gate driver circuit may further comprise a low-side off sensor that asserts a low-side off detection signal when a gate-source voltage of the low-side transistor falls below a predetermined threshold level, and a low-side off fixed switch connected between a gate and a source of the low-side transistor. When the output stage is in a current source mode, the control circuit may turn on the low-side off fixed switch in response to an assertion of the low-side off detection signal. As a result, self-turn-on of the low-side transistor can be prevented.

In an embodiment, when the output stage is in the current sink mode, the control circuit may set the low-side gate current that the low-side driver sinks from a gate of the low-side transistor to a fourth current amount in response to an instruction to turn off the low-side transistor, and may turn on the low-side off fixed switch in response to an assertion of the low-side off detection signal.

In the transition from a low output state to a high output state (or a high impedance state), when in a current source mode, the output voltage is kept at a voltage close to a ground voltage, so the fluctuations of the drain current of the low-side transistor are small. Therefore, by sinking the low-side gate current of the fourth current amount until the low-side transistor is completely turned off, the low-side transistor can be turned off in a short time.

In an embodiment, the gate driver circuit may be monolithically integrated on a single semiconductor substrate. “Monolithically integrated” includes a case where all components of the circuit are formed on a semiconductor substrate, or a case where main components of the circuit are monolithically integrated, and some resistors, capacitors, etc., for adjusting circuit constants may be provided outside the semiconductor substrate. By integrating the circuit onto a single chip, the circuit area can be reduced, and characteristics of circuit elements can be kept uniform.

In an embodiment, a motor driving circuit may comprise a switching circuit (output stage) including a high-side transistor and a low-side transistor, and one of the aforementioned gate driver circuits that drives the switching circuit (output stage).

In an embodiment, an electronic apparatus may comprise a motor and the aforementioned motor driving device that drives the motor.

### Embodiments

Hereinafter, preferable embodiments are illustrated with reference to figures. Identical or equivalent elements, components, processes shown in each figure are denoted by same reference numerals, and redundant illustrations are omitted as appropriate. Additionally, the embodiments are exemplary and do not limit the invention, and all features or combinations thereof illustrated in the embodiments are not necessarily essential to the invention.

In this specification, the phrase “a state in which component A is connected to component B” includes not only cases in which the component A and the component B are physically directly connected, but also cases in which the component A and the component B are indirectly connected to each other via other components that do not substantially affect their electrical connection state or do not impair functions or effects achieved by their combination.

Similarly, the phrase “a state in which component C is disposed between component A and component B” includes not only cases in which the component A and the component C, or the component B and the component C, are directly connected, but also cases in which they are indirectly connected via other components that do not substantially affect their electrical connection state or do not impair functions or effects achieved by their combination.

To begin with, problems that arise when a power transistor is turned off in a switching circuit are illustrated.

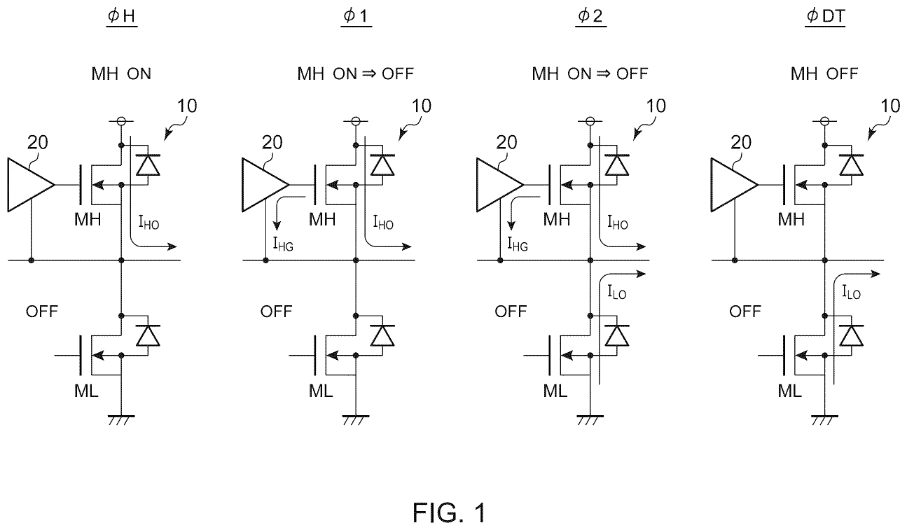

FIG. 1 is a circuit diagram illustrating a switching of a switching circuit 10. Herein, a turn-off operation of a high-side transistor is illustrated. The switching circuit 10 includes a high-side transistor MH and a low-side transistor ML arranged in series between a power supply terminal and a ground terminal.

The switching circuit 10 in FIG. 1 operates in a current source mode, and a current I_{OUT} is supplied from the switching circuit 10 to a load (not shown).

A state φ_{H} indicates a high output state where the high-side transistor MH is on and the low-side transistor ML is off. A high-side current I_{HO} flowing through the high-side transistor MH from a power supply line is supplied to the load as the output current I_{OUT}.

States φ1 and φ2 indicate a turn-off period of the high-side transistor MH. A high-side driver 20 pulls a gate current I_{HG} having a constant current from a gate of the high-side transistor MH and reduces a gate-source voltage of the high-side transistor MH over time. In the state φ1, the load current is primarily the high-side current I_{HO} flowing through the high-side transistor MH. In the state φ2, the load current is a sum of the high-side current I_{HO} flowing through the high-side transistor MH and a current I_{LO} flowing through a body diode of the low-side transistor ML.

State φ_{DT} indicates a dead time state where both the high-side transistor MH and the low-side transistor ML are off. At this time, the load is supplied by the body diode of the low-side transistor ML.

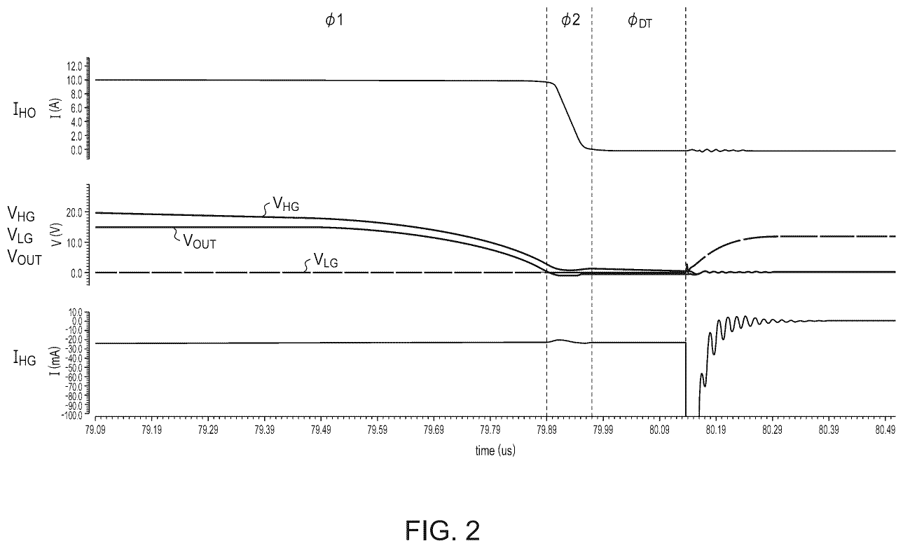

FIG. 2 is an operational waveform diagram of the switching circuit 10 in FIG. 1. In the states φ1 and φ2, the high-side driver 20 is assumed to sink a gate current I_{HG} having a constant amount from the gate of the high-side transistor MH. The gate current I_{HG} is taken as positive when flowing into the gate of the high-side transistor MH and negative when pulled from the gate.

In a control where the gate current I_{HG} is kept constant, if the gate current I_{HG} is small, the power consumption of the high-side transistor MH increases, and an amount of heat generated increases.

Conversely, if the gate current I_{HG} is increased, the power consumption of the high-side transistor MH decreases, but a slope of the high-side current I_{HO} flowing through the high-side transistor MH in the state φ2 becomes larger, and EMI becomes larger. Additionally, if a slope of the high-side current I_{HO} in the state φ2 is large, an output voltage V_{OUT} becomes a large negative voltage until the body diode of the low-side transistor ML conducts.

As such, in a control where the gate current I_{HG} is kept constant, there is a trade-off relationship between the power consumption of the high-side transistor MH, and EMI as well as the negative output voltage.

In the following, a gate driver circuit that can suppress EMI as well as negative voltage while suppressing power consumption is illustrated.

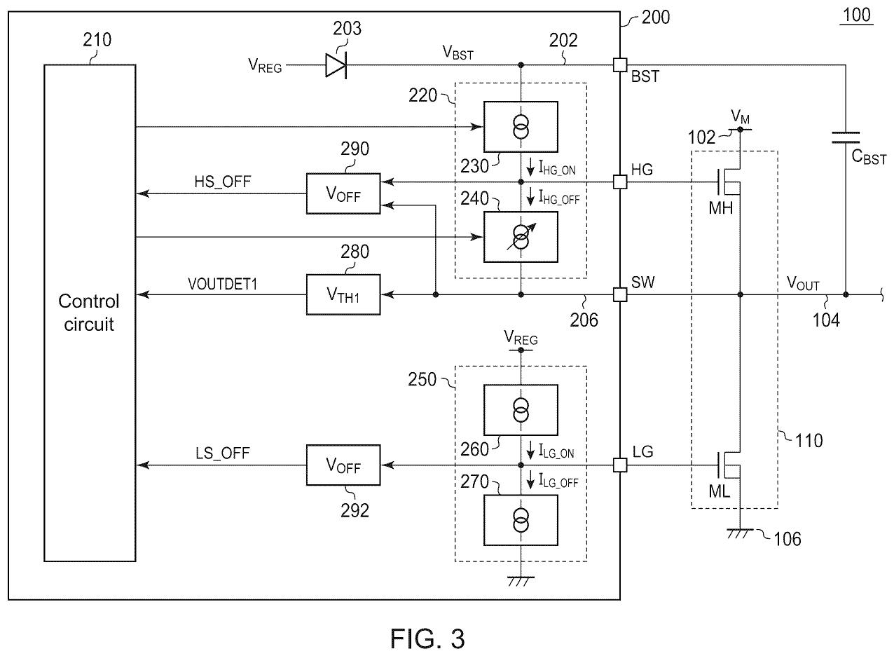

FIG. 3 is a circuit diagram of a switching circuit 100 according to an embodiment. The switching circuit 100 comprises an output stage 110 and a gate driver circuit 200. The output stage 110 is, for example, a bridge circuit. Herein, only a configuration of one phase of the switching circuit 100 is shown, but the switching circuit 100 may be a three-phase or H-bridge circuit.

The output stage 110 comprises a high-side transistor MH provided between a power supply line (input line) 102 and an output terminal (output line) 104, and a low-side transistor ML provided between the output line 104 and a ground line 106. An input voltage V_{M} is supplied to the input line 102. In this embodiment, the high-side transistor MH and the low-side transistor ML are N-channel MOSFETs, and their respective body diodes also serve as flywheel diodes.

The gate driver circuit 200 drives the high-side transistor MH and the low-side transistor ML of the output stage 110.

A bootstrap capacitor C_{BST} is connected between a bootstrap pin BST and the output line 104. A high-side gate pin HG is connected to a gate of the high-side transistor MH. A switching pin SW is connected to a source of the high-side transistor MH and a drain of the low-side transistor ML. A low-side gate pin LG is connected to a gate of the low-side transistor ML.

A bootstrap line 202 is connected to the bootstrap pin BST. A regulated voltage V_{REG} is applied to the bootstrap line 202 via a rectifying element 203. The rectifying element 203 and the bootstrap capacitor C_{BST} form a bootstrap circuit, maintaining a voltage V_{BST} on the bootstrap line 202 at V_{OUT}+V_{REG}−Vf. Vf is a forward voltage of the rectifying element 203.

The gate driver circuit 200 is a functional IC integrated on a single semiconductor substrate, comprising a control circuit 210, a high-side driver 220, a low-side driver 250, a first output sensor 280, a high-side off sensor 290, and a low-side off sensor 292. The control circuit 210 controls the high-side driver 220 and the low-side driver 250 according to a state of a load of the output stage 110.

The high-side driver 220 comprises a turn-on circuit 230 and a turn-off circuit 240. The turn-on circuit 230 becomes active when the high-side transistor MH is turned on and sources a gate current I_{HG_ON} to the gate of the high-side transistor MH. A gate capacitance of the high-side transistor MH is charged by the gate current I_{HG_ON}, and a gate-source voltage of the high-side transistor MH increases.

The turn-off circuit 240 becomes active when the high-side transistor MH is turned off and sinks a gate current I_{HG_OFF} from the gate of the high-side transistor MH. The gate capacitance of the high-side transistor MH is discharged by the gate current I_{HG_OFF}, and the gate-source voltage of the high-side transistor MH decreases.

The low-side driver 250 comprises a turn-on circuit 260 and a turn-off circuit 270. The turn-on circuit 260 becomes active when the low-side transistor ML is turned on and sources a gate current I_{LG_ON} to the gate of the low-side transistor ML. A gate capacitance of the low-side transistor ML is charged by the gate current I_{LG_ON}, and a gate-source voltage of the low-side transistor ML increases.

The turn-off circuit 270 becomes active when the low-side transistor ML is turned off and sinks a gate current I_{LG_OFF} from a gate of the low-side transistor ML. The gate capacitance of the low-side transistor ML is discharged by the gate current I_{LG_OFF}, and the gate-source voltage of the low-side transistor ML decreases.

The first output sensor 280 is connected to the switching line 206 and monitors the output voltage V_{OUT}. When the output voltage V_{OUT} falls below a first threshold voltage V_{TH1}, the first output sensor 280 asserts (for example, high) the first output detection signal VOUTDET1. The first threshold voltage V_{TH1} can be set around 0 V, and may be approximately 1 V.

The high-side off sensor 290 asserts (for example, high) a high-side off detection signal HS_OFF when it detects that the high-side transistor MH is turned off. For example, the high-side off sensor 290 compares a gate-source voltage V_{HGS} of the high-side transistor MH with a predetermined threshold voltage V_{OFF}, and when V_{HGS}<V_{OFF}, it asserts the high-side off detection signal HS_OFF.

The low-side off sensor 292 asserts (for example, high) a low-side off detection signal LS_OFF when it detects that the low-side transistor ML is turned off. For example, the low-side off sensor 292 compares a gate-source voltage V_{LGS} of the low-side transistor ML with a predetermined threshold voltage V_{OFF}, and when V_{LGS}<V_{OFF}, it asserts the low-side off detection signal LS_OFF.

In this embodiment, the turn-off circuit 240 of the high-side driver 220 is configured to switch the gate current I_{HG_OFF} pulled from the gate of the high-side transistor MH in a plurality of stages.

The control circuit 210 controls a current amount of the gate current I_{HG_OFF} generated by the turn-off circuit 240 in addition to turning the turn-off circuit 240 on and off.

Specifically, in an operation mode (source mode) in which an output current I_{OUT} of the output stage 110 flows out toward a load (not shown), the control circuit 210 controls the turn-off circuit 240 as follows.

The control circuit 210 sets the gate current I_{HG_OFF} of the turn-off circuit 240 to a first current amount I₁ in response to an instruction to turn off the high-side transistor MH. Then, in response to an assertion of the first output detection signal VOUTDET1, the gate current I_{HG_OFF} is set to a second current amount I₂, which is less than the first current amount I₁.

In response to an assertion of the high-side off detection signal HS_OFF, the control circuit 210 activates the low-side driver 250, and starts a turn-on operation of the low-side transistor ML.

Additionally, in response to the assertion of the high-side off detection signal HS_OFF, the control circuit 210 controls the turn-off circuit 240, and keeps a gate-source voltage V_{HGS} of the high-side transistor MH at 0 V. For example, the high-side driver 220 may comprise a high-side off fixed switch 222, which is an NMOS transistor connected between a gate and a source of the high-side transistor MH, and in response to the assertion of the high-side off detection signal HS_OFF, the high-side transistor MH may be kept in an off state by fully turning on the high-side off fixed switch 222. As a result, the high-side transistor MH can be prevented from self-turning on during the turn-on operation of the low-side transistor ML after the high-side transistor MH has been turned off.

Additionally, for example, if the turn-off circuit 240 includes an NMOS transistor connected between the gate and the source of the high-side transistor MH, this NMOS transistor may also be utilized as a high-side off fixed switch 222. In this case, the turn-off circuit 240 may include an off fixed switch connected between the gate and the source of the high-side transistor MH, and the gate-source voltage V_{HGS} of the high-side transistor MH may be kept at 0 V by turning on this off fixed switch.

The above is the configuration of the switching circuit 100. Next, its operation is illustrated.

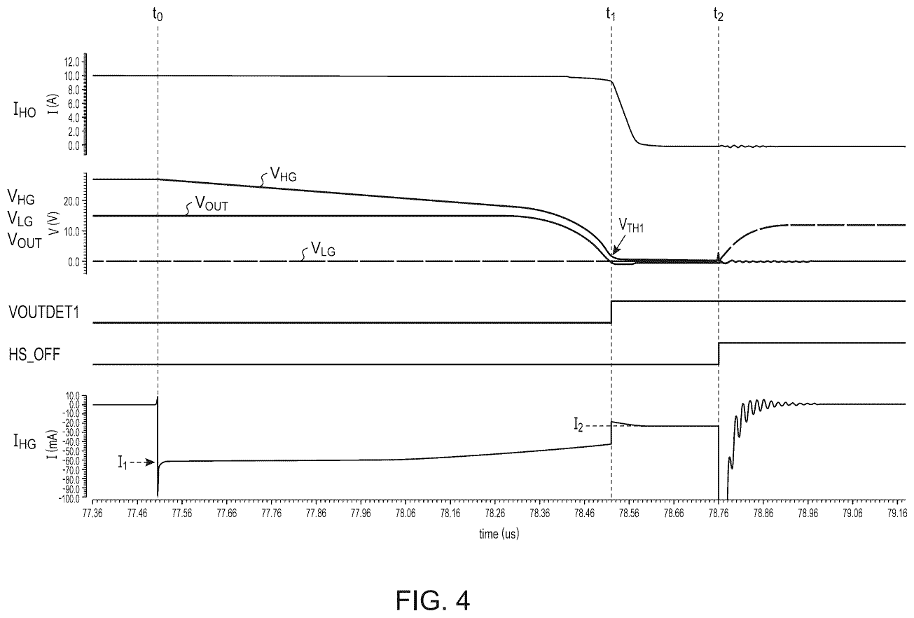

FIG. 4 is a waveform diagram illustrating an operation of the switching circuit 100 in FIG. 3. The switching circuit 100 operates in a current source mode. A method for determining between the current sink mode and the current source mode is not particularly limited and can be performed using known techniques (for example, Japanese Patent Publication No. H10-341588). Specifically, in the current source mode, the first output detection signal VOUTDET1 and the second output detection signal VOUTDET2 are asserted before the high-side off detection signal HS_OFF. Conversely, in the current sink mode, the high-side off detection signal HS_OFF is asserted before the first output detection signal VOUTDET1 and the second output detection signal VOUTDET2. Thus, the control circuit 210 may determine the current sink mode and the current source mode based on an order of changes in several detection signals.

At time t₀, when a command to turn off the high-side transistor MH is generated, the control circuit 210 sets the gate current I_{HG} to the first current amount I₁ and activates the turn-off circuit 240 of the high-side driver 220.

At time t₁, when the output voltage V_{OUT} falls below the first threshold voltage V_{TH1}, the first output detection signal VOUTDET1 is asserted. In response to the assertion of the first output detection signal VOUTDET1, the control circuit 210 sets the gate current I_{HG} to the second current amount I₂.

At time t₂, when the gate-source voltage V_{HGS} of the high-side transistor MH drops to the threshold voltage V_{OFF}, the high-side off detection signal HS_OFF is asserted.

When the high-side off detection signal HS_OFF is asserted, the gate-source voltage V_{HGS} of the high-side transistor MH is kept at 0 V.

Additionally, in response to the assertion of the high-side off detection signal HS_OFF, the low-side driver 250 becomes active and starts a turn-on operation of the low-side transistor ML.

The above is the operation of the switching circuit 100.

In the time chart of FIG. 4, a period t₀ to t₁ corresponds to the state φ1 in FIG. 1, and a period t₁ to t₂ corresponds to the state φ2 in FIG. 1. With the gate driver circuit 200 according to an embodiment, a transition from the state φ1 to φ2 is detected by the first output sensor 280, and in the state φ1, by increasing a current amount of the gate current I_{HG_OFF}, a turn-off time can be shortened, and the power consumption of the high-side transistor MH can be reduced. Additionally, in the state φ2, by decreasing the current amount of the gate current I_{HG_OFF}, a slope of the high-side current I_{HO} can be reduced, and EMI can be suppressed. Additionally, an occurrence of negative voltage in the output voltage V_{OUT} can be suppressed.

Then, after the turn-off of the high-side transistor MH is completed, by keeping the high-side transistor MH in an off state, the high-side transistor MH can be prevented from self-turning on during a subsequent turn-on operation of the low-side transistor ML.

Next, modification examples of the switching circuit 100 are illustrated.

In the embodiment of FIG. 3, the gate current I_{HG_OFF} is switched in two stages, but it may also be switched in three or more stages.

### Modification Example 1

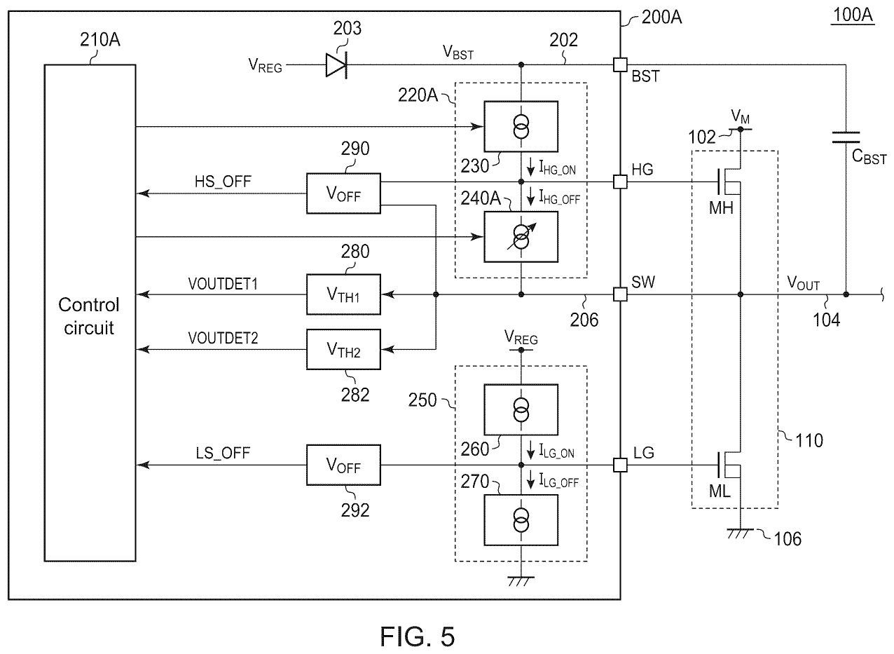

FIG. 5 is a circuit diagram of a switching circuit 100A according to a modification example 1. In the modification example 1, a turn-off circuit 240A of a high-side driver 220A is configured to allow the gate current I_{HG_OFF} to be switched in three stages. The high-side driver 220A may include a high-side off fixed switch 222, but this is omitted in FIG. 5 and subsequent figures.

The gate driver circuit 200A further comprises a second output sensor 282. The second output sensor 282 is connected to a switching line 206 and monitors the output voltage V_{OUT}. When the output voltage V_{OUT} falls below a second threshold voltage V_{TH2}, which is higher than the first threshold voltage V_{TH1}, the second output sensor 282 asserts (for example, high) a second output detection signal VOUTDET2. The second threshold voltage V_{TH2} can be set near an input voltage V_{M}. An assertion of the second output detection signal VOUTDET2 indicates a start of a transition of the output voltage V_{OUT}.

For example, it may be defined as V_{TH1}=V_{TH}, V_{TH2}=V_{M}−VTH. V_{TH} can be set to approximately 1 V.

In response to an instruction to turn off the high-side transistor MH, the control circuit 210A sets the gate current I_{HG_OFF} of the turn-off circuit 240A to the first current amount I₁.

Then, in response to an assertion of the second output detection signal VOUTDET2, the control circuit 210A sets the gate current I_{HG_OFF} of the turn-off circuit 240A to a third current amount I₃. The third current amount I₃ satisfies the relationship I₁>I₃>I₂.

Then, in response to the assertion of the first output detection signal VOUTDET1, the control circuit 210A sets the gate current I_{HG_OFF} of the turn-off circuit 240A to the second current amount I₂.

In response to an assertion of the high-side off detection signal HS_OFF, the control circuit 210A activates the low-side driver 250 and starts a turn-on operation of the low-side transistor ML.

The above is the configuration of the gate driver circuit 200A. Next, its operation is illustrated.

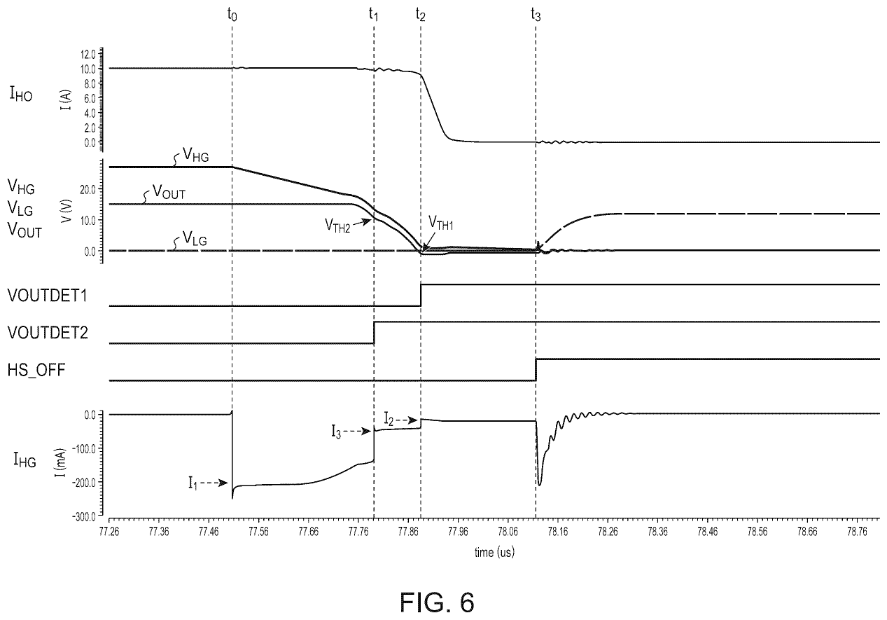

FIG. 6 is a waveform diagram illustrating an operation of the switching circuit 100A in FIG. 5. The switching circuit 100A operates in a current source mode.

At time t₀, when a command to turn off the high-side transistor MH is generated, the control circuit 210A sets the gate current I_{HG} to the first current amount I₁ and activates the turn-off circuit 240A of the high-side driver 220.

At time t₁, when the output voltage V_{OUT} falls below the second threshold voltage V_{TH2}, the second output detection signal VOUTDET2 is asserted. In response to the assertion of the second output detection signal VOUTDET2, the control circuit 210A sets the gate current I_{HG} to the third current amount I₃.

At time t₂, when the output voltage V_{OUT} falls below the first threshold voltage V_{TH1}, the first output detection signal VOUTDET1 is asserted. In response to the assertion of the first output detection signal VOUTDET1, the control circuit 210A sets the gate current I_{HG} to the second current amount I₂.

At time t₃, when the gate-source voltage V_{HGS} of the high-side transistor MH drops to the threshold voltage V_{OFF}, the high-side off detection signal HS_OFF is asserted. When the high-side off detection signal HS_OFF is asserted, the gate-source voltage V_{HGS} of the high-side transistor MH is kept at 0 V.

Additionally, in response to the assertion of the high-side off detection signal HS_OFF, the low-side driver 250 becomes active and starts the turn-on operation of the low-side transistor ML.

The above is the operation of the switching circuit 100A.

According to the modification example 1, by adding the second output sensor 282, in an interval corresponding to the state φ1 in FIG. 1, the gate current I_{HG_OFF} can be switched in two stages: the first current amount I₁ and the third current amount I₃. As a result, the first current amount I₁ in the modification example 1 can be made larger than the first current amount I₁ in the embodiment, and as a result, the turn-off time can be further shortened, and the power consumption of the high-side transistor MH can be further reduced.

### Modification Example 2

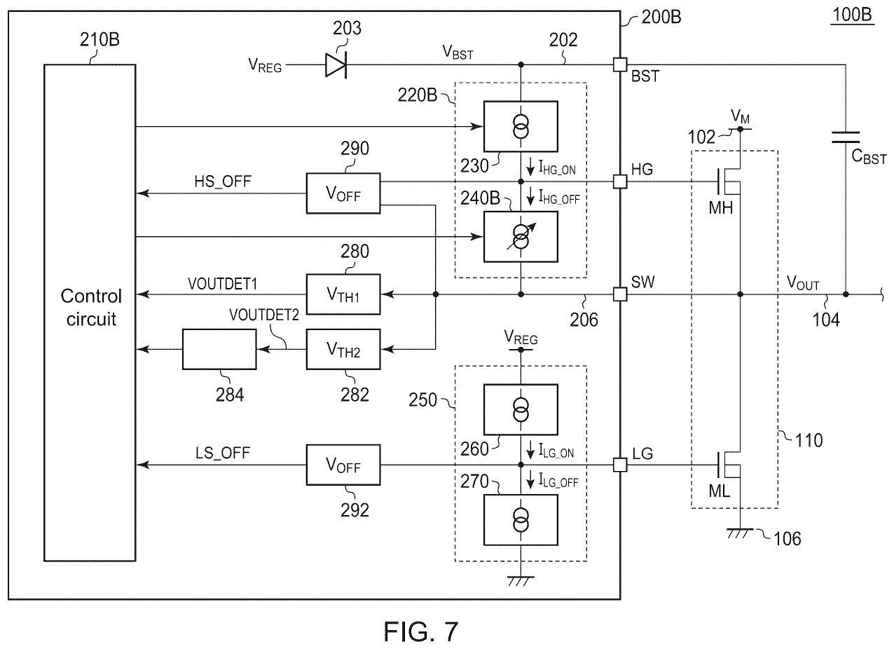

FIG. 7 is a circuit diagram of a switching circuit 100B according to a modification example 2.

The gate driver circuit 200B further comprises a first delay circuit 284. The first delay circuit 284 delays the second output detection signal VOUTDET2 by a certain delay time τd. In response to an assertion of the delayed second output detection signal VOUTDET2, the control circuit 280B switches the gate current I_{HG_OFF} from the first current amount I₁ to the third current amount I₃.

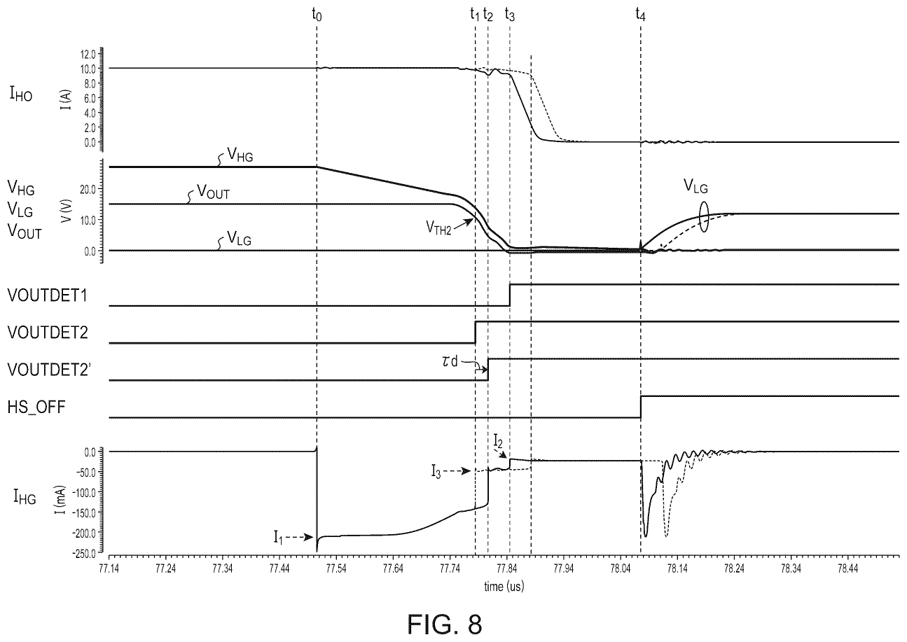

FIG. 8 is a waveform diagram illustrating an operation of the switching circuit 100B in FIG. 7. The switching circuit 100B operates in a current source mode. In FIG. 8, an operational waveform of the switching circuit 100A according to the modification example 1 is shown with a dashed line.

At time t₀, when a command to turn off the high-side transistor MH is generated, the control circuit 210B sets the gate current I_{HG} to the first current amount I₁ and activates the turn-off circuit 240B of the high-side driver 220.

At time t₁, when the output voltage V_{OUT} falls below the second threshold voltage V_{TH2}, the second output detection signal VOUTDET2 is asserted, and at time t₂ after a delay time τd has elapsed, the output VOUTDET2′ of the first delay circuit 284 is asserted. In response to an assertion of the delayed second output detection signal VOUTDET2, the control circuit 210B sets the gate current I_{HG} to the third current amount I₃.

At time t₃, when the output voltage V_{OUT} falls below the first threshold voltage V_{TH1}, the first output detection signal VOUTDET1 is asserted. In response to the assertion of the first output detection signal VOUTDET1, the control circuit 210B sets the gate current I_{HG} to the second current amount I₂.

At time t₄, when the gate-source voltage V_{HGS} of the high-side transistor MH drops to the threshold voltage V_{OFF}, the high-side off detection signal HS_OFF is asserted. When the high-side off detection signal HS_OFF is asserted, the gate-source voltage V_{HGS} of the high-side transistor MH is kept at 0 V.

Additionally, in response to the assertion of the high-side off detection signal HS_OFF, the low-side driver 250 becomes active and starts the turn-on operation of the low-side transistor ML.

The above is the operation of the switching circuit 100B.

According to this modification example 2, compared to the modification example 1, a time during which the gate current I_{HG_OFF} is set to the first current amount I₁ is extended by the delay time τd. As a result, compared to the modification example 1, the turn-off time of the high-side transistor MH can be further shortened, and efficiency can be improved.

In the above illustrations, the turn-off of the high-side transistor MH when operating in the current source mode is illustrated. In the following modification examples, similar control is applied to the turn-off of the low-side transistor ML when operating in a current sink mode.

### Modification Example 3

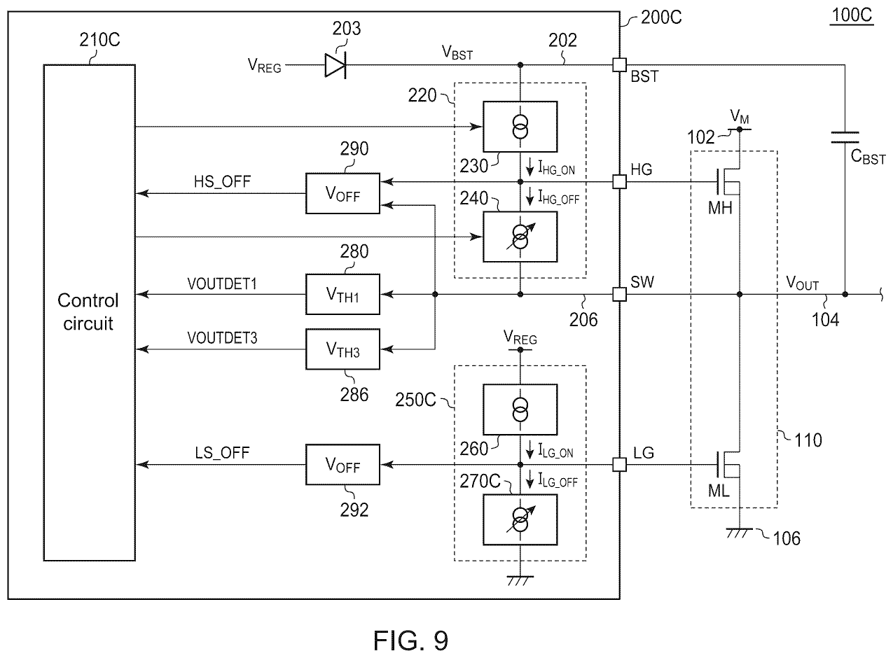

FIG. 9 is a circuit diagram of a switching circuit 100C according to a modification example 3. A gate driver circuit 200C applies the control of the gate driver circuit 200 in FIG. 3 to the low-side transistor ML as well.

In the gate driver circuit 200C, a turn-off circuit 270C of a low-side driver 250C is configured to switch a current I_{LG_OFF} sunk from a gate of the low-side transistor ML in two stages when the low-side transistor ML is turned off.

Additionally, the gate driver circuit 200C further comprises a third output sensor 286 in addition to the gate driver circuit 200 in FIG. 3. The third output sensor 286 monitors the output voltage V_{OUT}. When the output voltage V_{OUT} exceeds a third threshold voltage V_{TH3}, the third output sensor 286 asserts (for example, high) a third output detection signal VOUTDET3. The third threshold voltage V_{TH3} can be set near the input voltage V_{M}. For example, it may be set as V_{TH1}=V_{TH}, V_{TH3}=V_{M}−V_{TH}.

The control circuit 210C controls a current amount of the gate current I_{LG_OFF} generated by the turn-off circuit 270C in addition to turning the turn-off circuit 270C on and off.

Specifically, in the operating mode (current sink mode) in which the output current I_{OUT} of the output stage 110 flows into a load (not shown), the control circuit 210C controls the turn-off circuit 270C as follows.

In response to an instruction to turn off the low-side transistor ML, the control circuit 210C sets the gate current I_{LG_OFF} of the turn-off circuit 270C to a fourth current amount I₄. Then, in response to an assertion of the third output detection signal VOUTDET3, the gate current I_{LG_OFF} is set to a fifth current amount I₅, which is less than the fourth current amount I₄.

In response to an assertion of the low-side off detection signal LS_OFF, the control circuit 210C activates the high-side driver 220 and starts a turn-on operation of the high-side transistor MH.

Additionally, in response to an assertion of the low-side off detection signal LS_OFF, the control circuit 210C controls the turn-off circuit 270C, and keeps a gate-source voltage V_{LGS} of the low-side transistor ML at 0 V. For example, the low-side driver 250C may comprise a low-side off fixed switch 252, which is an NMOS transistor connected between a gate and a source of the low-side transistor ML, and in response to an assertion of a low-side off detection signal HS_OFF, the low-side transistor ML may be kept in an off state by fully turning on the low-side off fixed switch 252. As a result, the low-side transistor ML can be prevented from self-turning on during the turn-on operation of the high-side transistor MH after the low-side transistor ML has been turned off.

Additionally, for example, if the turn-off circuit 270C includes an NMOS transistor connected between the gate and the source of the low-side transistor ML, this NMOS transistor may also be utilized as the low-side off fixed switch 252. In this case, the turn-off circuit 270 may include an off fixed switch connected between the gate and the source of the low-side transistor ML, and by turning on this off fixed switch, the gate-source voltage V_{LGS} of the low-side transistor ML may be kept at 0 V.

The above is the configuration of the gate driver circuit 200C. According to this modification example 3, EMI can be suppressed while reducing the power consumption of the low-side transistor ML.

### Modification Example 4

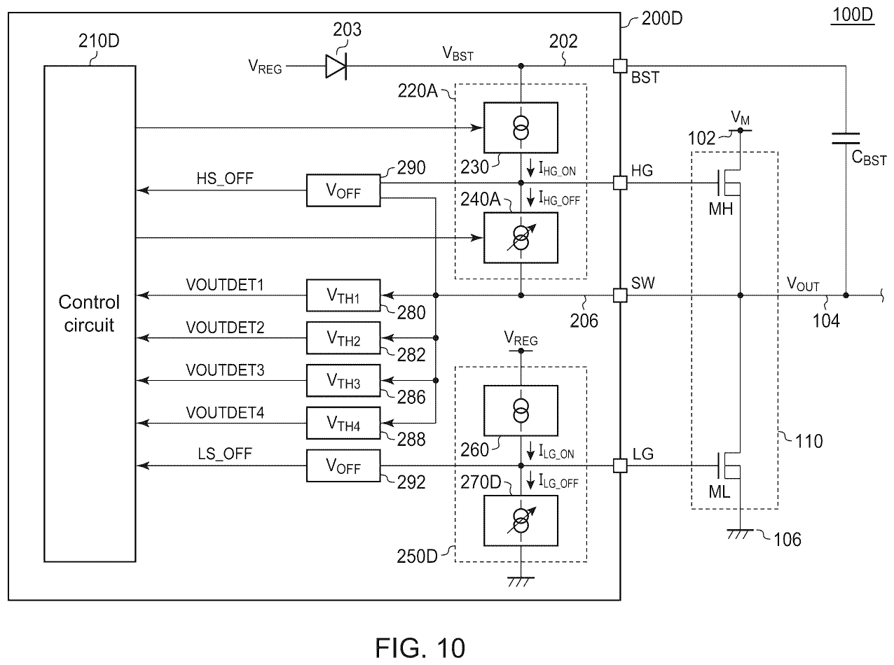

FIG. 10 is a circuit diagram of a switching circuit 100D according to a modification example 4. The gate driver circuit 200D applies the control of the gate driver circuit 200A in FIG. 5 to the low-side transistor ML as well.

The gate driver circuit 200D comprises a third output sensor 286 and a fourth output sensor 288 in addition to the gate driver circuit 200A in FIG. 5.

The fourth output sensor 288 asserts a fourth output detection signal VOUTDET4 when the output voltage V_{OUT} exceeds a fourth threshold voltage V_{TH4}. The fourth threshold voltage V_{TH4} can be set near 0 V. For example, each threshold voltage may be defined as follows.

$$\begin{matrix}{V}_{TH 1} = {V}_{TH} \\ {V}_{TH 2} = {V}_{M} - {V}_{TH} \\ {V}_{TH 3} = {V}_{M} - {V}_{TH} \\ {V}_{TH 4} = {V}_{TH}\end{matrix}$$

In this case, the same output sensor can be used as the first output sensor 280 and the fourth output sensor 288, and the same output sensor can be used as the second output sensor 282 and the third output sensor 286. By using one output sensor as output sensors with equal threshold voltages, an increase in circuit area can be suppressed.

In response to an instruction to turn off the low-side transistor ML, a control circuit 210D sets a gate current I_{HG_OFF} of a turn-off circuit 270D to the fourth current amount I₄.

Then, in response to an assertion of the fourth output detection signal VOUTDET4, the control circuit 210D sets the gate current I_{LG_OFF} of the turn-off circuit 270D to a sixth current amount I₆. The sixth current amount I₆ satisfies the relationship I₄>I₆>I₅.

Then, in response to an assertion of the third output detection signal VOUTDET3, the control circuit 210D sets the gate current I_{LG_OFF} of the turn-off circuit 270D to the fifth current amount I₅.

In response to an assertion of the low-side off detection signal LS_OFF, the control circuit 210D activates the high-side driver 220A and starts the turn-on operation of the high-side transistor MH.

Additionally, in response to an assertion of the low-side off detection signal LS_OFF, the control circuit 210D controls the turn-off circuit 270D, and keeps a gate-source voltage V_{LGS} of the low-side transistor ML at 0 V.

### Modification Example 5

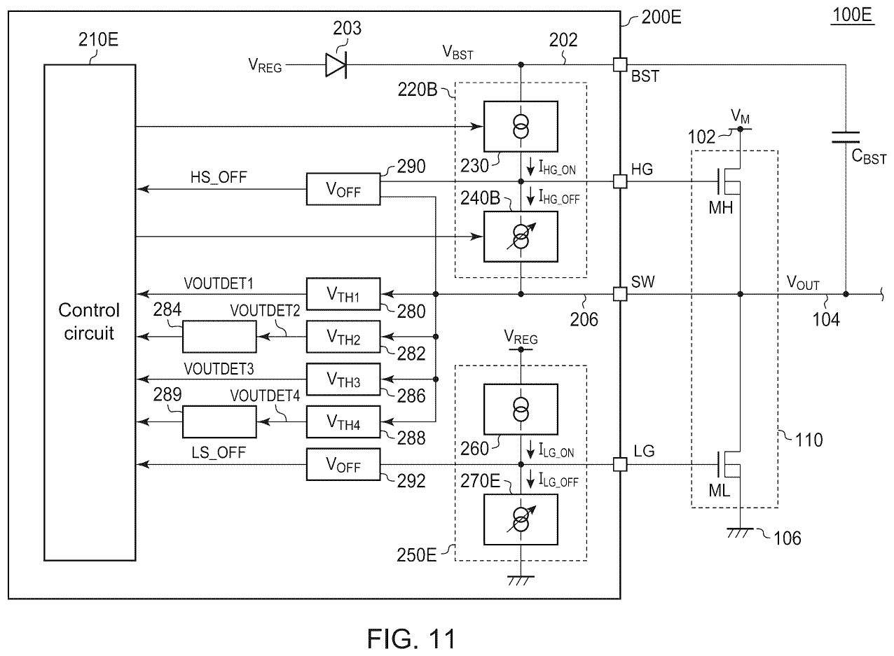

FIG. 11 is a circuit diagram of a switching circuit 100E according to a modification example 5. The gate driver circuit 200E applies the control of the gate driver circuit 200B in FIG. 7 to the low-side transistor ML as well.

The gate driver circuit 200E comprises a third output sensor 286, a fourth output sensor 288, and a second delay circuit 289, in addition to the gate driver circuit 200B in FIG. 7.

The second delay circuit 289 delays the fourth output detection signal VOUTDET4. In response to the delayed fourth output detection signal VOUTDET4, the control circuit 210E sets the gate current I_{LG_OFF} of the turn-off circuit 270E to the sixth current amount I₆.

Next, a transition operation of the switching circuit 100 from a high output state φ_{H} to a low output state φ_{L} (or a high impedance state) when the output stage 110 is in a current sink mode is illustrated.

When the output stage 110 is in a current sink mode, since the output voltage V_{OUT} is maintained near a high voltage (input voltage) V_{IN} and there is almost no change in the output voltage V_{OUT}, a drain current of the high-side transistor MH is substantially constant, and EMI is unlikely to occur.

When the output stage 110 is in the current sink mode, in response to an instruction to turn off the high-side transistor MH, the control circuit 210 sets a high-side gate current I_{HG_OFF} to the first current amount I₁. Then, in response to an assertion of the high-side off detection signal HS_OFF, the high-side off fixed switch 222 is turned on.

The above is the turn-off operation of the high-side transistor MH in the current sink mode. In the current sink mode, since there is no transition in the output voltage V_{OUT} during the turn-off of the high-side transistor MH, by sinking the high-side gate current I_{HG_OFF} of the first current amount I₁ until the high-side transistor MH is turned off, the high-side transistor MH can be turned off in a short time.

Next, a transition operation of the switching circuit 100 from the low output state φ_{L} to the high output state φ_{H} (or the high impedance state) when the output stage 110 is in a current source mode is illustrated.

When the output stage 110 is in the current source mode, since the output voltage V_{OUT} is maintained at a low voltage (ground voltage) of around 0 V and there is almost no change in the output voltage V_{OUT}, a drain current of the low-side transistor ML is substantially constant, and EMI is unlikely to occur.

When the output stage 110 is in the current source mode, in response to an instruction to turn off the low-side transistor ML, the control circuit 210 sets the low-side gate current I_{LG_OFF} to the fourth current amount I₄. Then, in response to an assertion of the low-side off detection signal LS_OFF, the off fixed switch 252 is turned on.

The above is the turn-off operation of the low-side transistor ML in the current source mode. In the current source mode, since there is no transition in the output voltage V_{OUT} during the turn-off of the low-side transistor ML, by sinking the low-side gate current I_{LG_OFF} of the fourth current amount I₄ until the low-side transistor ML is turned off, the low-side transistor ML can be turned off in a short time.

### Application

Next, applications of the switching circuit 100 are illustrated. The switching circuit 100 can be suitably used in motor driving circuits.

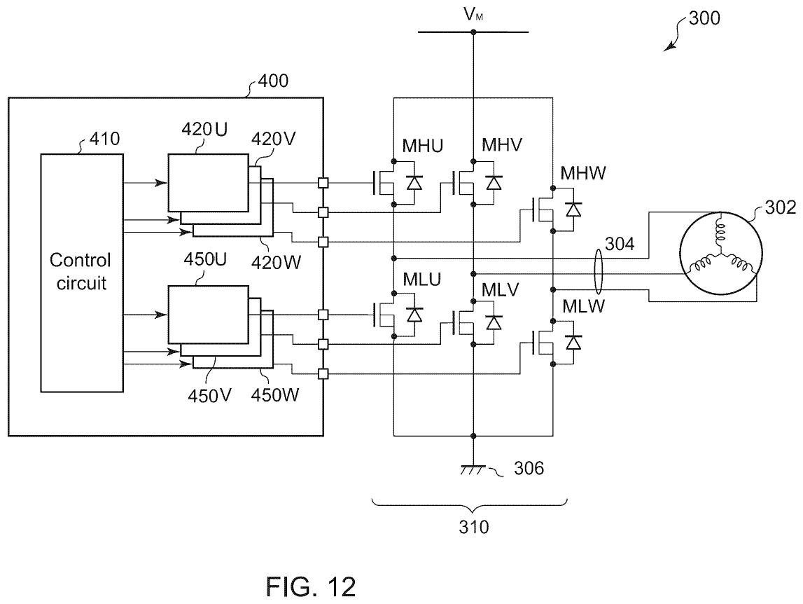

FIG. 12 is a circuit diagram of a motor driving device 300 according to an embodiment. The motor driving device 300 drives a three-phase motor 302, which is a load, and controls a rotational state.

The motor driving device 300 comprises an output stage 310 and a gate driver circuit 400. The output stage 310 is, for example, a bridge circuit. The output stage 310 is a three-phase inverter comprising U-phase, V-phase, and W-phase legs, and each phase leg comprises a high-side transistor MH and a low-side transistor ML.

The gate driver circuit 400 comprises a control circuit 410, high-side drivers 420U to 420W, and low-side drivers 450U to 450W. The control circuit 410 generates control signals that indicate states of six arms constituting the output stage 310 based on a state of the three-phase motor 302, which is the load.

The high-side drivers 420U to 420W are configured based on an architecture of the aforementioned high-side driver 220. Additionally, the low-side drivers 450U to 450W are configured based on an architecture of the aforementioned low-side driver 250.

Although a three-phase motor is used as an example herein, a single-phase motor may also be used. In this case, the bridge circuit 310 would be an H-bridge circuit.

Next, applications of the motor driving device 300 are illustrated. The motor driving device 300 can be utilized to control a spindle motor of a hard disk, or to control a motor for driving lens of an imaging device. Alternatively, it can also be utilized for printer head driving motors or to drive paper feeding motors. Alternatively, the motor driving device 300 can be utilized to drive motors in electric vehicles, hybrid vehicles, etc.

The embodiments are examples, and it is understood by those skilled in the art that various modification examples are possible in combinations of each component and each processing step, and such modification examples are also within the scope of the present disclosure or the present invention. These modification examples are illustrated below.

### Modification Example 1

In an embodiment, the output stage 110 is configured with discrete components, but this is not limitative, and the output stage 110 may be integrated into the gate driver circuit 200.

### Modification Example 2

An upper arm 112 and a lower arm 114 may be configured by an IGBT (Insulated Gate Bipolar Transistor).

### Modification Example 3

The application of the switching circuit 100 is not limited to the motor driving device 300. For example, the switching circuit 100 can be suitably utilized in switching regulators (DC/DC converters), various power conversion devices (inverters and converters), inverters for lighting discharge lamps, digital audio amplifiers, etc. Therefore, the switching circuit 100 can be utilized in consumer devices including electronic equipment and home appliances, automobiles and in-vehicle components, industrial vehicles and industrial machinery.

The embodiments illustrated using specific terms are merely illustrative of principles and applications of the present invention, and many modification examples and changes in arrangement are permitted in the embodiments without departing from the spirit of the present invention as defined in the claims.

### Appendix

The following technologies are disclosed in this specification.

### Item 1

A gate driver circuit, driving a high-side transistor and a low-side transistor that constitute a switching circuit, comprising:
a high-side driver driving the high-side transistor;
a low-side driver driving the low-side transistor;
a first output sensor asserting a first output detection signal when an output voltage of the switching circuit drops to a first threshold voltage; and
a control circuit controlling the high-side driver and the low-side driver,
wherein when the switching circuit is in a source mode, the control circuit
sets a high-side gate current that the high-side driver sinks from a gate of the high-side transistor to a first current amount in response to an instruction to turn off the high-side transistor, and
sets the high-side gate current to a second current amount that is less than the first current amount in response to an assertion of the first output detection signal.

### Item 2

The gate driver circuit of Item 1, further comprising a second output sensor that asserts a second output detection signal when the output voltage drops to a second threshold that is lower by a predetermined voltage than an input voltage of the switching circuit,
wherein the control circuit
sets the high-side gate current to a third current amount that is less than the first current amount in response to an assertion of the second output detection signal.

### Item 3

The gate driver circuit of Item 2, further comprising a first delay circuit that delays the second output detection signal,
wherein the control circuit sets the high-side gate current to the third current amount in response to an assertion of the delayed second output detection signal.

### Item 4

The gate driver circuit of any of Items 1 to 3, further comprising a third output sensor that asserts a third output detection signal when the output voltage of the switching circuit rises to a third threshold voltage,
wherein when the switching circuit is in a sink mode, the control circuit
sets the low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

### Item 5

The gate driver circuit of Item 4, further comprising a fourth output sensor that asserts a fourth output detection signal when the output voltage rises to a fourth threshold that is lower by a predetermined voltage than the input voltage of the switching circuit,
wherein the control circuit
sets the low-side gate current to a fifth current amount that is less than the fourth current amount in response to an assertion of the fourth output detection signal.

### Item 6

The gate driver circuit of Item 5, further comprising a second delay circuit that delays the fourth output detection signal,
wherein the control circuit sets the low-side gate current to the fifth current amount in response to an assertion of the delayed fourth output detection signal.

### Item 7

A gate driver circuit, driving a high-side transistor and a low-side transistor that constitute a switching circuit, comprising:
a high-side driver driving the high-side transistor;
a low-side driver driving the low-side transistor;
a third output sensor asserting a third output detection signal when an output voltage of the switching circuit rises to a third threshold voltage; and
a control circuit controlling the high-side driver and the low-side driver,
wherein when the switching circuit is in a sink mode, the control circuit
sets a low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

### Item 8

The gate driver circuit of Item 7, further comprising a fourth output sensor that asserts a fourth output detection signal when the output voltage rises to a fourth threshold that is lower by a predetermined voltage than the input voltage of the switching circuit,
wherein the control circuit
sets the low-side gate current to a fifth current amount that is less than the fourth current amount in response to an assertion of the fourth output detection signal.

### Item 9

The gate driver circuit of Item 8, further comprising a second delay circuit that delays the fourth output detection signal,
wherein the control circuit sets the low-side gate current to the fifth current amount in response to an assertion of the delayed fourth output detection signal.

### Item 10

The gate driver circuit of any of Items 1 to 9, being monolithically integrated on a single semiconductor substrate.

### Item 11

A motor driving device, comprising:
a switching circuit including a high-side transistor and a low-side transistor; and
the gate driver circuit of any of Items 1 to 10 driving the switching circuit.

### Item 12

An electronic apparatus, comprising:
a motor; and
the motor driving device of Item 11 driving the motor.

### Item 13

A gate driver circuit, driving a high-side transistor and a low-side transistor that constitute an output stage, comprising:
a high-side driver driving the high-side transistor;
a low-side driver driving the low-side transistor;
a first output sensor asserting a first output detection signal when an output voltage of the output stage drops to a first threshold voltage; and
a control circuit controlling the high-side driver and the low-side driver,
wherein when the output stage is in a current source mode, the control circuit
sets a high-side gate current that the high-side driver sinks from a gate of the high-side transistor to a first current amount in response to an instruction to turn off the high-side transistor, and
sets the high-side gate current to a second current amount that is less than the first current amount in response to an assertion of the first output detection signal.

### Item 14

The gate driver circuit of Item 13, further comprising a second output sensor that asserts a second output detection signal when the output voltage drops to a second threshold that is lower by a predetermined voltage than an input voltage of the output stage,
wherein when the output stage is in a current source mode, the control circuit
sets the high-side gate current to a third current amount that is less than the first current amount in response to an assertion of the second output detection signal.

### Item 15

The gate driver circuit of Item 14, further comprising a first delay circuit that delays the second output detection signal,
wherein when the output stage is in a current source mode, the control circuit sets the high-side gate current to the third current amount in response to an assertion of the delayed second output detection signal.

### Item 16

The gate driver circuit of any of Items 13 to 15, further comprising:
a high-side off sensor asserting a high-side off detection signal when a gate-source voltage of the high-side transistor falls below a predetermined threshold level; and
a high-side off fixed switch connected between a gate and a source of the high-side transistor,
wherein when the output stage is in a current source mode, the control circuit turns on the high-side off fixed switch in response to an assertion of the high-side off detection signal.

### Item 17

The gate driver circuit of Item 16, wherein when the output stage is in a current sink mode, the control circuit
sets the high-side gate current that the high-side driver sinks from the gate of the high-side transistor to a first current amount in response to an instruction to turn off the high-side transistor, and
turns on the high-side off fixed switch in response to an assertion of the high-side off detection signal.

### Item 18

The gate driver circuit of any of Items 13 to 15, further comprising a third output sensor that asserts a third output detection signal when the output voltage of the output stage rises to a third threshold voltage,
wherein when the output stage is in a current sink mode, the control circuit
sets the low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

### Item 19

The gate driver circuit of Item 18, further comprising a fourth output sensor that asserts a fourth output detection signal when the output voltage rises to a fourth threshold that is lower by a predetermined voltage than the input voltage of the output stage,
wherein when the output stage is in a current sink mode, the control circuit sets the low-side gate current to a fifth current amount that is less than the fourth current amount in response to an assertion of the fourth output detection signal.

### Item 20

The gate driver circuit of Item 19, further comprising a second delay circuit that delays the fourth output detection signal,
wherein when the output stage is in a current sink mode, the control circuit sets the low-side gate current to the fifth current amount in response to an assertion of the delayed fourth output detection signal.

### Item 21

The gate driver circuit of Item 18, further comprising:
a low-side off sensor asserting a low-side off detection signal when a gate-source voltage of the low-side transistor falls below a predetermined threshold level; and
a low-side off fixed switch connected between a gate and a source of the low-side transistor,
wherein when the output stage is in a current source mode, the control circuit turns on the low-side off fixed switch in response to an assertion of the low-side off detection signal.

### Item 22

The gate driver circuit of Item 21, wherein when the output stage is in a current sink mode, the control circuit
sets the low-side gate current that the low-side driver sinks from the gate of the low-side transistor to a fourth current amount in response to an instruction to turn off the low-side transistor, and
turns on the low-side off fixed switch in response to an assertion of the low-side off detection signal.

### Item 23

A gate driver circuit, driving a high-side transistor and a low-side transistor that constitute an output stage, comprising:
a high-side driver driving the high-side transistor;
a low-side driver driving the low-side transistor;
a third output sensor asserting a third output detection signal when an output voltage of the output stage rises to a third threshold voltage; and
a control circuit controlling the high-side driver and the low-side driver,
wherein when the output stage is in a current sink mode, the control circuit
sets a low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

### Item 24

The gate driver circuit of Item 23, further comprising a fourth output sensor that asserts a fourth output detection signal when the output voltage rises to a fourth threshold that is lower by a predetermined voltage than an input voltage of the output stage,
wherein the control circuit
sets the low-side gate current to a fifth current amount that is less than the fourth current amount in response to an assertion of the fourth output detection signal.

### Item 25

The gate driver circuit of Item 24, further comprising a second delay circuit that delays the fourth output detection signal,
wherein the control circuit sets the low-side gate current to the fifth current amount in response to an assertion of the delayed fourth output detection signal.

### Item 26

The gate driver circuit of any of Items 23 to 25, further comprising:
a low-side off sensor asserting a low-side off detection signal when a gate-source voltage of the low-side transistor falls below a predetermined threshold level; and
a low-side off fixed switch connected between a gate and a source of the low-side transistor,
wherein when the output stage is in a current source mode, the control circuit turns on the low-side off fixed switch in response to an assertion of the low-side off detection signal.

### Item 27

The gate driver circuit of Item 26, wherein when the output stage is in a current sink mode, the control circuit
sets the low-side gate current that the low-side driver sinks from the gate of the low-side transistor to a fourth current amount in response to an instruction to turn off the low-side transistor, and
turns on the low-side off fixed switch in response to an assertion of the low-side off detection signal.

### Item 28

The gate driver circuit of any of Items 13 to 15, 23 to 25, being monolithically integrated on a single semiconductor substrate.

### Item 29

A motor driving device, comprising:
an output stage including a high-side transistor and a low-side transistor; and
the gate driver circuit of any of Items 13 to 15, 23 to 25 driving the output stage.

### Item 30

An electronic apparatus, comprising:
a motor; and
the motor driving device of Item 29 driving the motor.

1. A gate driver circuit, driving a high-side transistor and a low-side transistor that constitute a switching circuit, comprising:
a high-side driver driving the high-side transistor;
a low-side driver driving the low-side transistor;
a first output sensor asserting a first output detection signal when an output voltage of the switching circuit drops to a first threshold voltage; and
a control circuit controlling the high-side driver and the low-side driver,
wherein when the switching circuit is in a source mode, the control circuit
sets a high-side gate current that the high-side driver sinks from a gate of the high-side transistor to a first current amount in response to an instruction to turn off the high-side transistor, and
sets the high-side gate current to a second current amount that is less than the first current amount in response to an assertion of the first output detection signal.

2. The gate driver circuit of claim 1, further comprising a second output sensor that asserts a second output detection signal when the output voltage drops to a second threshold that is lower by a predetermined voltage than an input voltage of the switching circuit,
wherein the control circuit
sets the high-side gate current to a third current amount that is less than the first current amount in response to an assertion of the second output detection signal.

3. The gate driver circuit of claim 2, further comprising a first delay circuit that delays the second output detection signal,
wherein the control circuit sets the high-side gate current to the third current amount in response to an assertion of the delayed second output detection signal.

4. The gate driver circuit of claim 1, further comprising a third output sensor that asserts a third output detection signal when the output voltage of the switching circuit rises to a third threshold voltage,
wherein when the switching circuit is in a sink mode, the control circuit
sets the low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

5. The gate driver circuit of claim 4, further comprising a fourth output sensor that asserts a fourth output detection signal when the output voltage rises to a fourth threshold that is lower by a predetermined voltage than the input voltage of the switching circuit,
wherein the control circuit
sets the low-side gate current to a fifth current amount that is less than the fourth current amount in response to an assertion of the fourth output detection signal.

6. The gate driver circuit of claim 5, further comprising a second delay circuit that delays the fourth output detection signal,
wherein the control circuit sets the low-side gate current to the fifth current amount in response to an assertion of the delayed fourth output detection signal.

7. A gate driver circuit, driving a high-side transistor and a low-side transistor that constitute a switching circuit, comprising:
a high-side driver driving the high-side transistor;
a low-side driver driving the low-side transistor;
a third output sensor asserting a third output detection signal when an output voltage of the switching circuit rises to a third threshold voltage; and
a control circuit controlling the high-side driver and the low-side driver,
wherein when the switching circuit is in a sink mode, the control circuit
sets a low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

8. The gate driver circuit of claim 7, further comprising a fourth output sensor that asserts a fourth output detection signal when the output voltage rises to a fourth threshold that is lower by a predetermined voltage than the input voltage of the switching circuit,
wherein the control circuit
sets the low-side gate current to a fifth current amount that is less than the fourth current amount in response to an assertion of the fourth output detection signal.

9. The gate driver circuit of claim 8, further comprising a second delay circuit that delays the fourth output detection signal,
wherein the control circuit sets the low-side gate current to the fifth current amount in response to an assertion of the delayed fourth output detection signal.

10. The gate driver circuit of claim 1, being monolithically integrated on a single semiconductor substrate.

11. A motor driving device, comprising:
a switching circuit including a high-side transistor and a low-side transistor; and
the gate driver circuit of claim 1 driving the switching circuit.

12. An electronic apparatus, comprising:
a motor; and
the motor driving device of claim 11 driving the motor.

13. A gate driver circuit, driving a high-side transistor and a low-side transistor that constitute an output stage, comprising:
a high-side driver driving the high-side transistor;
a low-side driver driving the low-side transistor;
a first output sensor asserting a first output detection signal when an output voltage of the output stage drops to a first threshold voltage; and
a control circuit controlling the high-side driver and the low-side driver,
wherein when the output stage is in a current source mode, the control circuit
sets a high-side gate current that the high-side driver sinks from a gate of the high-side transistor to a first current amount in response to an instruction to turn off the high-side transistor, and
sets the high-side gate current to a second current amount that is less than the first current amount in response to an assertion of the first output detection signal.

14. The gate driver circuit of claim 13, further comprising a second output sensor that asserts a second output detection signal when the output voltage drops to a second threshold that is lower by a predetermined voltage than an input voltage of the output stage,
wherein when the output stage is in a current source mode, the control circuit
sets the high-side gate current to a third current amount that is less than the first current amount in response to an assertion of the second output detection signal.

15. The gate driver circuit of claim 14, further comprising a first delay circuit that delays the second output detection signal,
wherein when the output stage is in a current source mode, the control circuit sets the high-side gate current to the third current amount in response to an assertion of the delayed second output detection signal.

16. The gate driver circuit of claim 13, further comprising:
a high-side off sensor asserting a high-side off detection signal when a gate-source voltage of the high-side transistor falls below a predetermined threshold level; and
a high-side off fixed switch connected between a gate and a source of the high-side transistor,
wherein when the output stage is in a current source mode, the control circuit turns on the high-side off fixed switch in response to an assertion of the high-side off detection signal.

17. The gate driver circuit of claim 16, wherein when the output stage is in a current sink mode, the control circuit
sets the high-side gate current that the high-side driver sinks from the gate of the high-side transistor to a first current amount in response to an instruction to turn off the high-side transistor, and
turns on the high-side off fixed switch in response to an assertion of the high-side off detection signal.

18. The gate driver circuit of claim 13, further comprising a third output sensor that asserts a third output detection signal when the output voltage of the output stage rises to a third threshold voltage,
wherein when the output stage is in a current sink mode, the control circuit
sets the low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

19. The gate driver circuit of claim 18, further comprising a fourth output sensor that asserts a fourth output detection signal when the output voltage rises to a fourth threshold that is lower by a predetermined voltage than the input voltage of the output stage,
wherein when the output stage is in a current sink mode, the control circuit sets the low-side gate current to a fifth current amount that is less than the fourth current amount in response to an assertion of the fourth output detection signal.

20. The gate driver circuit of claim 19, further comprising a second delay circuit that delays the fourth output detection signal,
wherein when the output stage is in a current sink mode, the control circuit sets the low-side gate current to the fifth current amount in response to an assertion of the delayed fourth output detection signal.

21. The gate driver circuit of claim 18, further comprising:
a low-side off sensor asserting a low-side off detection signal when a gate-source voltage of the low-side transistor falls below a predetermined threshold level; and
a low-side off fixed switch connected between a gate and a source of the low-side transistor,
wherein when the output stage is in a current source mode, the control circuit turns on the low-side off fixed switch in response to an assertion of the low-side off detection signal.

22. The gate driver circuit of claim 21, wherein when the output stage is in a current sink mode, the control circuit
sets the low-side gate current that the low-side driver sinks from the gate of the low-side transistor to a fourth current amount in response to an instruction to turn off the low-side transistor, and
turns on the low-side off fixed switch in response to an assertion of the low-side off detection signal.

23. A gate driver circuit, driving a high-side transistor and a low-side transistor that constitute an output stage, comprising:
a high-side driver driving the high-side transistor;
a low-side driver driving the low-side transistor;
a third output sensor asserting a third output detection signal when an output voltage of the output stage rises to a third threshold voltage; and
a control circuit controlling the high-side driver and the low-side driver,
wherein when the output stage is in a current sink mode, the control circuit
sets a low-side gate current that the low-side driver sinks from a gate of the low-side transistor to a fourth current amount in response to an instruction to turn off the low-side transistor, and
sets the low-side gate current to a fifth current amount that is less than the fourth current amount in response to an assertion of the third output detection signal.

24. The gate driver circuit of claim 23, further comprising a fourth output sensor that asserts a fourth output detection signal when the output voltage rises to a fourth threshold that is lower by a predetermined voltage than an input voltage of the output stage,
wherein the control circuit
sets the low-side gate current to a fifth current amount that is less than the fourth current amount in response to an assertion of the fourth output detection signal.

25. The gate driver circuit of claim 24, further comprising a second delay circuit that delays the fourth output detection signal,
wherein the control circuit sets the low-side gate current to the fifth current amount in response to an assertion of the delayed fourth output detection signal.

26. The gate driver circuit of claim 23, further comprising:
a low-side off sensor asserting a low-side off detection signal when a gate-source voltage of the low-side transistor falls below a predetermined threshold level; and
a low-side off fixed switch connected between a gate and a source of the low-side transistor,
wherein when the output stage is in a current source mode, the control circuit turns on the low-side off fixed switch in response to an assertion of the low-side off detection signal.

27. The gate driver circuit of claim 26, wherein when the output stage is in a current sink mode, the control circuit
sets the low-side gate current that the low-side driver sinks from the gate of the low-side transistor to a fourth current amount in response to an instruction to turn off the low-side transistor, and
turns on the low-side off fixed switch in response to an assertion of the low-side off detection signal.

28. The gate driver circuit of claim 13, being monolithically integrated on a single semiconductor substrate.

29. A motor driving device, comprising:
an output stage including a high-side transistor and a low-side transistor; and
the gate driver circuit of claim 13 driving the output stage.

30. An electronic apparatus, comprising:
a motor; and
the motor driving device of claim 29 driving the motor.
